(19) United States
(12) Patent Application Publication
(10) Pub. No.: US 2002/0186859 A1
(43) Pub. Date: Dec. 12, 2002

(54) Framework for home theater systems

(76) Inventor: Gerardo W. Atia, Canyon Country, CA (US)

Correspondence Address: KELLY BAUERSFELD LOWRY & KELLEY, LLP, 6320 CANOGA AVENUE, SUITE 1650, WOODLAND HILLS, CA, 91367, US

(21) Appl. No.: 10/171,345

(22) Filed: Jun. 12, 2002

Related U.S. Application Data
(60) Provisional application No. 60/297,731, filed on Jun. 12, 2001.

(51) Int. Cl. H05K 5/00; H04R 1/02

(52) U.S. Cl. 381/386; 181/149

(57) ABSTRACT

A framework for home theater system speakers includes a ceiling mount assembly having ceiling mounts fastenable to the ceiling, connectors detachably connected to the ceiling mounts, and cables extending downwardly from the connectors. Sub-frame members are interconnected to create a frame, which is connected to the cable so as to be suspended from the ceiling. The frame is hollow and houses speaker wiring. Speakers are supported at positions substantially surrounding a viewing or listening area to provide a surround sound effect.

### RELATED APPLICATION

This application claims priority from Provisional Application Serial No. 60/297,731 filed Jun. 12, 2001.

### BACKGROUND OF THE INVENTION

The present invention relates to stereo and home theater equipment. More particularly, the present invention relates to speaker installation hardware.

Recent developments in home theater equipment have created a need for an improved method of installing speakers and other hardware used in home theater systems. Many home theaters have signal decoders that split the audio signal into five or more separate audio signals. These home theater systems require a separate speaker for each audio signal. Having separate signals and speakers is essential to providing the high quality surround sound that most home theaters offer. The proper placement of the surround sound speakers is important in obtaining high quality surround sound. In general, a surround sound system includes front left and right speakers, rear left and right speakers, and a center channel. To obtain the surround sound effect, the rear speakers are generally placed evenly apart and behind the sitting area, the front speakers on either side of the TV, and the center speaker above or below the TV.

In most cases, the speakers are placed on furniture or attached to walls. In many instances, placing the speakers in the proper spot is not possible because the wall or furniture is not and cannot be placed in the right spot. Speakers might have to be placed at the wrong angle, height or distance needed for quality surround sound performance. In addition, speakers that are mounted on the wall may cause the wall to vibrate and disturb the room next door. This is particularly a problem in an apartment setting where the home theater system may disturb adjoining neighbors.

Another problem with home theater installation are the speaker wires that most people do not want left exposed. Exposed wires can create numerous problems. People may trip on them or children may play with them or pull on them. The wires could get cut by a vacuum cleaner. Some people simply prefer that the wires be hidden for aesthetic purposes. Hiding wires can be problematic. To hang a speaker on the wall, holes have to be drilled in the wall to run the wire through the wall. In addition, baseboards may have to be taken off and in most cases the carpet has to be pulled up. These methods of installation are often difficult and leave permanent or expensive damage. Those who rent their home or property may not be allowed to make such modifications.

Accordingly, there is a need for a device that will allow a person to conveniently and properly install speakers and components of a home theater system without causing significant or irreparable damage while concealing the wiring of the system. The present invention fulfills these needs and provides other related advantages.

### SUMMARY OF THE INVENTION

The present invention resides in an apparatus that forms a framework, which holds electronic hardware, such as projectors, screens, speakers and speaker wire, and that can be easily attached to a ceiling or wall. Wiring for home theater equipment can be conveniently run through the framework such that the wiring is inconspicuous. The framework for home theater system speakers embodying the present invention generally comprises a ceiling mount assembly attachable to a ceiling, and a frame connected to cables extending downwardly from the ceiling mount assembly so as to be suspended from the ceiling. The frame is configured to support speakers at positions substantially surrounding a viewing or listening area to provide a surround sound effect.

The ceiling mount assembly includes ceiling mounts fastenable to the ceiling. Typically, the ceiling mounts include an aperture through which a bolt or screw is inserted for fastening to the ceiling. Ceiling mount connectors are attached to ends of the cable generally opposite the frame and detachably connected to the ceiling mounts. In a particularly preferred embodiment, the ceiling mounts include internal threads which receive external threads of the connectors such that the connectors and ceiling mounts are threadably connected to one another.

At least a portion of the frame is hollow and includes speaker wiring disposed therein. Typically, the frame includes speaker supporting brackets at predetermined positions on the frame.

In a particularly preferred embodiment, the frame comprises interconnected sub-frame members. A coupler of reduced diameter has a first end inserted within an open end of a first sub-frame member, and a second end inserted into an adjoining second sub-frame member to connect the sub-frame members. Alternatively, an end of a first sub-frame member is of reduced diameter so as to fit within an adjoining second sub-frame member. The sub-frame members and coupler include apertures for the insertion of bolts to secure the sub-frame members to one another. Generally, L-shaped frame members form corners of the frame, and straight frame members are attached to and interconnect the L-shaped frame members.

Other features and advantages of the present invention will become apparent from the following more detailed description, taken in conjunction with the accompanying drawings, which illustrate, by way of example, the principles of the invention.

### BRIEF DESCRIPTION OF THE DRAWINGS

The accompanying drawings illustrate the invention. In such drawings:

FIG. 1 is a perspective view of a framework for a home theater system embodying the present invention, and having a television and speakers attached thereto;

FIG. 2 is a perspective view of an exemplary frame used in accordance with the present invention;

FIGS. 3A-3D are perspective views of assorted sub-frame components that can be assembled to create a frame in accordance with the present invention;

FIG. 4 is a perspective view of a plurality of sub-frame components interconnected with one another to form a portion of a frame;

FIG. 5 is a perspective view of a wall mount connector used in accordance with the present invention;

FIG. 6 is a perspective view of a ceiling mount assembly used in accordance with the present invention;

FIG. 7 is an exploded perspective view of the ceiling mount assembly of FIG. 6, illustrated in the various component parts thereof;

FIG. 8 is a perspective view of the frame of FIG. 1 suspended from a ceiling using a plurality of ceiling mount assemblies; and

FIG. 9 is a perspective view similar to FIG. 8, but illustrating the frame suspended from a sloping ceiling.

### DETAILED DESCRIPTION OF THE PREFERRED EMBODIMENT

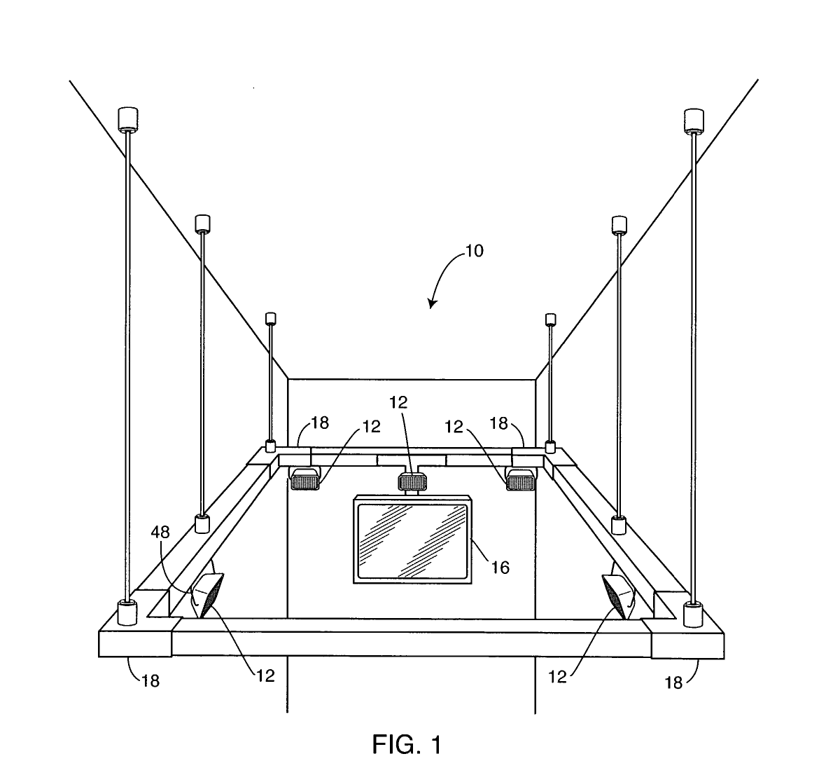

As shown in the drawings for purposes of illustration, the present invention is concerned with a framework, generally referred to by the reference number 10, for home theater systems having speakers 12 positioned for a surround sound effect. As shown in FIG. 1, the framework 10 is designed so as to suspend the speakers 12 over a viewing or listening area to provide an optimal surround sound effect without regard to the size of the room in which the framework 10 is placed, or without regard to the viewing or listening area.

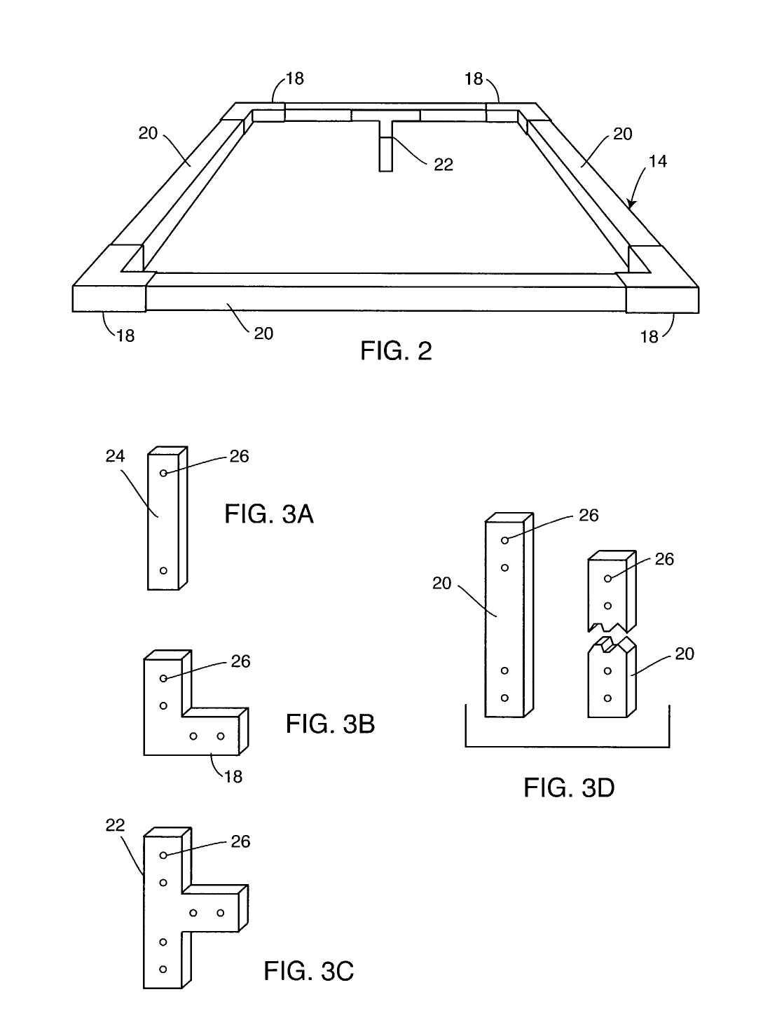

With reference to FIGS. 1 and 2, the framework 10 of the present invention includes a frame 14 comprised of durable yet light weight material, such as extruded aluminum or plastic or the like. The frame 14 is configured to support speakers 12 at positions substantially surrounding the viewing or listening area to provide the desired surround sound effect. A particularly preferred quadrilateral frame 14 is illustrated in the accompanying drawings which has been found to be relatively easy to manufacture and install and provides the necessary support points for positioning the speakers over the viewing or listening area. FIG. 1 illustrates a preferred arrangement of speakers 12, whereby two front speakers are attached to the framework approximately equidistant from a television or projection screen 16, and two speakers are attached to opposite ends of the frame 14 at a rear portion of the viewing or listening area, and a center channel speaker is positioned generally over the television or projection screen 16.

With reference now to FIGS. 3A-3D and FIG. 4, the frame 14 is comprised of interconnected sub-frame members. For example, FIG. 3B illustrates a generally L-shaped sub-frame member 18 that is typically used to form the corners of the frame 14. FIG. 3D illustrates a generally straight sub-frame member 20 that serves as an extension and forms a side of the frame 14. It should be understood that the straight extension sub-frame member 20 can be of various lengths to create a frame 14 of various sizes to fit the needs of the particular room in which the framework 10 of the present invention is installed. A “T” sub-frame connector 22 can be used in the frame 14 to make an arm that supports a flat plasma screen or projection screen 16, as illustrated in FIG. 1, a projector (not shown), or serve as an insertion point for speaker wiring and the like. The frame 14 is typically tubular and hollow so as to accept speaker wiring therein for electrical attachment of the speakers 12 at the desired positions along the length of the framework 14.

As illustrated in FIG. 4, a frame 14 of desired configuration and size is created by interconnecting the various sub-frame members 18-22 to one another. This can be accomplished in a variety of ways. For example, an end of a particular sub-frame member may be of reduced cross-sectional diameter so as to fit into an adjacent end of another sub-frame member so as to interconnect the two to one another. However, in a particularly preferred embodiment, the invention utilizes couplers 24, illustrated in FIG. 3A which are of reduced cross-sectional diameter relative to the sub-frame members 18-22. As shown in FIG. 4, a first end of the coupler 24 is inserted into an open end of a sub-frame member, for example the T-sub-frame connector 22 with at least a portion of the coupler 24 extending therefrom. An adjoining sub-frame member, such as the illustrated extension sub-frame member 20 or L-shaped sub-frame member 18 is then fit over the exposed portion of the coupler 24 so that the sub-frame member 18 or 20 is positioned adjacent to the first sub-frame member, in this case, the T-sub-frame connector 22. The coupler 24 and sub-frame member 18-22 may form a frictional tight fit. In order to more securely interconnect the sub-frame members 18-22 to one another, the sub-frame members 18-22 and coupler 24 include apertures 26 therethrough which can be aligned with one another for the insertion of a bolt or the like.

The frame 14 may take on many different shapes, as needed, to ensure that the home theater speakers 12 and components can be positioned ideally for home theater use. The frame 14 is made into a desirable shape by assembling the various sub-frame components 18-22 into the desired configuration. Typically, a rectangular frame 14 is assembled as shown in the various figures. The frame 14 can take on any length or width by using different lengths of straight sub-frame extension members 20, or connecting shorter extension sub-frame connecting members 20 with the couplers 24. Potentially, the frame 14 can take on any shape by altering the sub-frame members so that such have angles other than 180° or 90°, so as to create, for example, a circle or ellipse.

The sub-frame members 18-22 and coupler 24 are all hollow whereby the connection of such members make a hollow frame 14. The hollowness of the frame 14 allows for wiring, such as for speakers, to be strung throughout the frame 14 so that the wiring is hidden. The speaker wire could enter and exit the frame 14 through an open end, such as the illustrated T-sub-frame member 22, or through apertures 26 within the frame 14. The invention also contemplates internal speaker wires that do not exit the frame 14, but rather connect permanent terminals whereby speakers or components may be plugged directly into the frame 14.

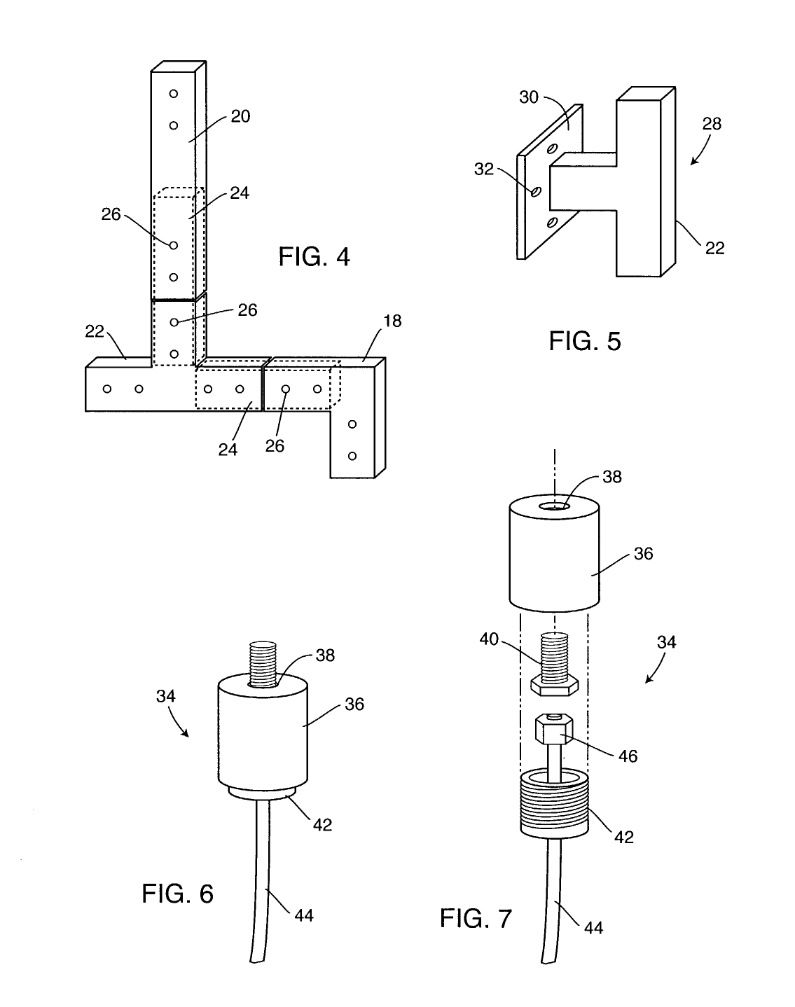

With reference now to FIG. 5, the frame 14 and accompanying speakers 12 and other home theater components is suspended above the desired viewing or listening area. In a first embodiment, this comprises the use of wall connectors 28 which essentially comprise a “T” sub-frame connector 22 or the like and a wall plate 30. The wall plate 30 attaches to the “T” sub-frame connector 22 or is permanently formed therewith. Thus, the wall connector 28 can be incorporated into the frame 14 through the “T” connector member 22 as described above. The wall plate 30 includes apertures 32 through which screws or the like are inserted for attachment to the desired position on the wall.

More preferably, the frame 14 is suspended from a ceiling through the use of a ceiling mount assembly 34, as shown in FIGS. 6 and 7. Such assembly 34 includes a ceiling mount 36 having an aperture 38 therethrough for insertion of a bolt 40 or the like which secures the ceiling mount 36 to the desired spot on the ceiling. A ceiling mount connector 42 is attached to an end of a cable 44 and removably attached to the ceiling mount 36. In a particularly preferred embodiment, the ceiling mount 36 is hollow and includes internal threads (not shown) and accepts the externally threaded connector 42. The ceiling mount connector 42 includes an aperture through which the cable 44 is introduced. A free end of the cable 44 is inserted through the connector 42 and a stop 46 or the like is attached to an end thereof to prevent the cable 44 from exiting the connector 42.

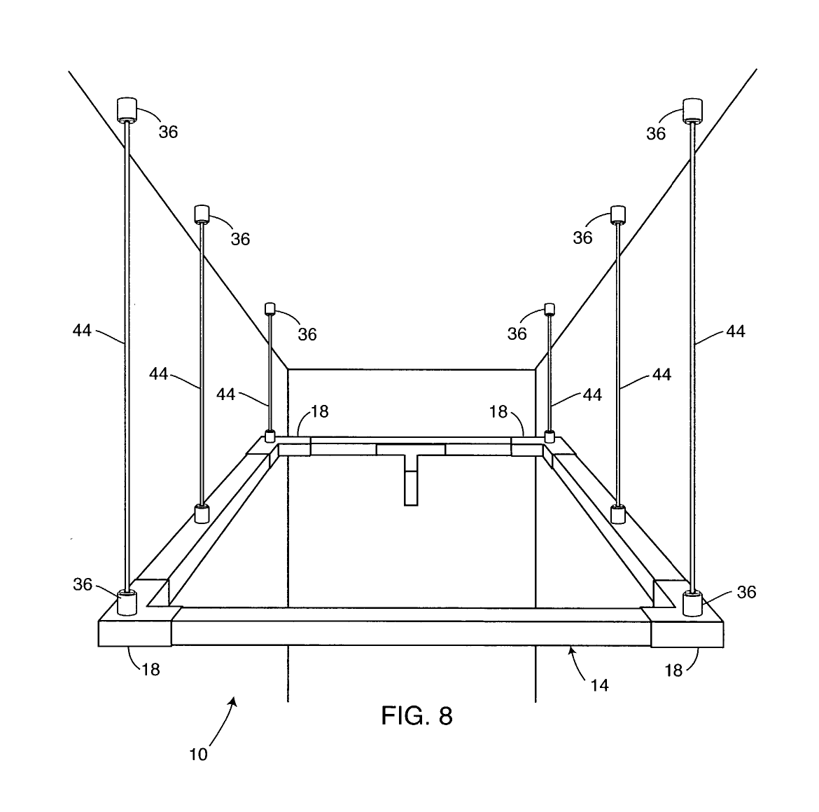

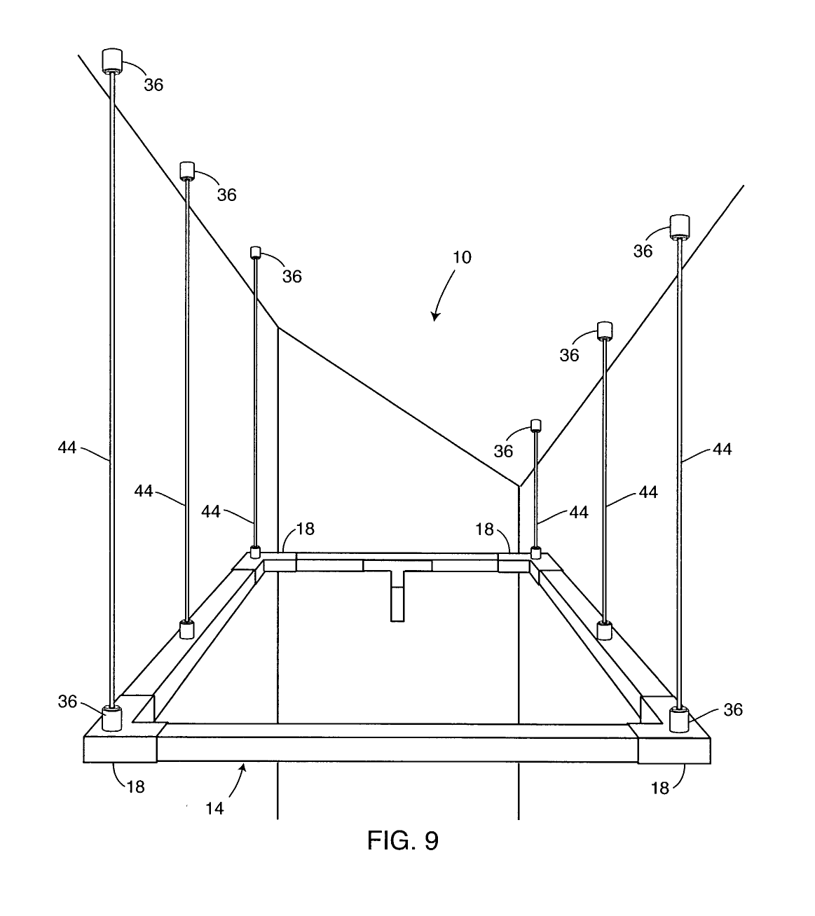

Referring now to FIGS. 8 and 9, the ceiling mounts 36 are secured to the ceiling at the desired points. Four to six ceiling mounts 36 are typically required depending upon the size of the frame 14 and listening or viewing area. The ceiling mount connector 42 having the cable 44 extending downwardly therefrom is then connected to the ceiling mount 36. Opposite ends of the cables 44 are then attached to the frame 14 by any appropriate method, such as looping the cable 44 through an eye-connector or the like, inserting the end of the cable 44 through an aperture and attaching the end of the cable 44 with a stop to prevent the cable 44 from exiting the frame 14, or utilizing a ceiling mount 36 and connector 42 connection, as described above, and as illustrated in FIGS. 8 and 9.

Use of the ceiling mount assembly 34 of the present invention allows the frame 14 and associated home theater components and speakers 12 to be positioned at the desired height by altering the length of the cables 44. As shown in FIG. 9, the present invention also allows the frame 14 to be suspended from sloping or uneven ceilings while retaining the frame 14 in a generally parallel or horizontal position.

The speaker wiring (not shown) is fed from the home theater audio system to the frame 14, as described above. The television 16 or the like may be kept in a armoire or cabinet on the floor of the room, or if a projection screen or plasma-type television, mounted on the frame 14 as illustrated in FIG. 1. After suspending the frame 14 from the ceiling or walls, as described above, the speakers 12 are then attached thereto, typically with the use of brackets 48 or the like which support and hold the speakers 12 in place on the frame 14.

The versatility of the present invention provides many needed benefits, including the ability to position components of the home theater system for optimal performance. The present invention also makes it possible for a person to install a home theater system in almost any room, including a room with a cathedral ceiling. The framework 10 of the present invention makes installation of a home theater system easy, convenient, and improves the esthetics of the room. Many people who rent an apartment who would otherwise not be able to install a home theater system may be able to do so with the present invention since it allows for installation with minimal damage. The framework 10 also provides the benefit of making the home theater system children-safe since the framework 10 is hung from the ceiling out of reach of the children.

Although several embodiments of the present invention have been described in detail for purposes of illustration, various modifications of each may be made without departing from the spirit and scope of the invention. Accordingly, the invention is not to be limited, except as by the appended claims.

What is claimed is:

1. A framework for home theater system speakers, comprising:
a ceiling mount assembly attachable to a ceiling, and including downwardly extending cables; and
a frame connected to the cables so as to be suspended from the ceiling, and configured to support speakers at positions substantially surrounding a viewing or listening area to provide a surround sound effect.

2. The framework of claim 1, wherein the frame includes speaker wiring disposed therein.

3. The framework of claim 2, wherein at least a portion of the frame is hollow.

4. The framework of claim 1, wherein the frame comprises interconnected sub-frame members.

5. The framework of claim 4, including generally L-shaped sub-frame members forming corners of the frame, and straight sub-frame members attached to and interconnecting the L-shaped sub-frame members to form a generally quadrilateral frame.

6. The framework of claim 4, wherein an end of a first sub-frame member is of reduced diameter so as to fit within an adjoining second sub-frame member.

7. The framework of claim 6, wherein the sub-frame members include apertures for the insertion of bolts to secure the sub-frame members to one another.

8. The framework of claim 4, including a coupler having a first end insertable into a first sub-frame member and a second end thereof insertable into a second sub-frame member to connect the first and second sub-frame members.

9. The framework of claim 8, wherein the coupler and sub-frame members include alignable apertures for the insertion of bolts to secure the sub-frame members to the coupler.

10. The framework of claim 1, wherein the ceiling mount assembly includes ceiling mounts fastenable to the ceiling, and connectors attached to ends of the cables generally opposite the frame and detachably connected to the ceiling mounts.

11. The framework of claim 10, wherein the ceiling mounts and connectors include mating threads.

12. The framework of claim 11, wherein the ceiling mounts include internal threads which receive external threads of the connectors.

13. The framework of claim 8, wherein the ceiling mounts include an aperture through which a bolt or screw is inserted for fastening to the ceiling.

14. The framework of claim 1, wherein the frame includes speaker supporting brackets attached thereto.

15. A framework for home theater system speakers, comprising:
a ceiling mount assembly including ceiling mounts fastenable to the ceiling, connectors detachably connected to the ceiling mounts, and cables extending downwardly from the connectors;
a frame connected to the cables so as to be suspended from the ceiling, the frame comprising interconnected sub-frame members and being configured to support speakers at positions substantially surrounding a viewing or listening area to provide a surround sound effect, and
speaker supporting brackets attached to the frame;
wherein at least a portion of the frame is hollow and includes speaker wiring disposed therein.

16. The framework of claim 15, including generally L-shaped sub-frame members forming corners of the frame, and straight sub-frame members attached to and interconnecting the L-shaped sub-frame members to form a generally quadrilateral frame.

17. The framework of claim 15, wherein an end of a first sub-frame member is of reduced diameter so as to fit within an adjoining second sub-frame member, and wherein the sub-frame members include apertures for the insertion of bolts to secure the sub-frame members to one another.

18. The framework of claim 15, including a coupler having a first end insertable into a first sub-frame member and a second end thereof insertable into a second sub-frame member to connect the first and second sub-frame members, and wherein the coupler and sub-frame members include alignable apertures for the insertion of bolts to secure the sub-frame members to the coupler.

19. The framework of claim 15, wherein the ceiling mounts include an aperture through which a bolt or screw is inserted for fastening to the ceiling and internal threads which receive external threads of the connectors.

20. A framework for home theater system speakers, comprising:
a ceiling mount assembly including ceiling mounts having an aperture through which a bolt or screw extends for fastening to the ceiling, connectors detachably connected to the ceiling mounts, and cables extending downwardly from the connectorrs; and
a frame connected to the cables so as to be suspended from the ceiling, the frame comprising couplers interconnecting sub-frame members; and
brackets attached to the frame for supporting speakers at positions substantially surrounding a viewing or listening area to provide a surround sound effect;
wherein at least a portion of the frame is hollow and includes speaker wiring disposed therein.

21. The framework of claim 20, including generally L-shaped sub-frame members forming corners of the frame, and straight sub-frame members attached to and interconnecting the L-shaped sub-frame members to from a generally quadrilateral frame.

22. The framework of claim 20, wherein the sub-frame members and couplers include alignable apertures for the insertion of bolts to secure the sub-frame members to one another.
